(19) United States
(12) Patent Application Publication
(10) Pub. No.: US 2024/0396284 A1
(43) Pub. Date: Nov. 28, 2024

(54) GAS LASER DEVICE AND ELECTRONIC DEVICE MANUFACTURING METHOD

(71) Applicant: Gigaphoton Inc., Tochigi (JP)

(72) Inventors: Takeshi UEYAMA, Oyama-shi (JP); Hiroshi UMEDA, Oyama-shi (JP)

(73) Assignee: Gigaphoton Inc., Tochigi (JP)

(21) Appl. No.: 18/796,335

(22) Filed: Aug. 7, 2024

Related U.S. Application Data
(63) Continuation of application No. PCT/JP2022/008669, filed on Mar. 1, 2022.

(51) Int. Cl. H01S 3/097; G03F 7/00

(52) U.S. Cl. CPC H01S 3/09702; G03F 7/70025; G03F 7/70991

(57) ABSTRACT

A gas laser device includes a power source, a main capacitor, a solid-state switch, a step-up transformer, a first magnetic pulse compression circuit including a first transfer capacitor and a first magnetic switch, and connected to a secondary side of the step-up transformer, a second magnetic pulse compression circuit including a second transfer capacitor and a second magnetic switch, and connected subsequently to the first magnetic pulse compression circuit, a peaking capacitor connected subsequently to the second magnetic pulse compression circuit, a pair of discharge electrodes, a regenerative transformer transferring charges generated by the discharge electrodes to the main capacitor after main discharge, and a reset circuit resetting the first magnetic switch and the second magnetic switch. Potential of the cathode electrode in a period of 0.5 μs to 20 μs both inclusive after the main discharge starts is within a range of −200 V to 200 V both inclusive.

### CROSS-REFERENCE TO RELATED APPLICATIONS

The present application claims the benefit of International Application No. PCT/JP2022/008669, filed on Mar. 1, 2022, the entire contents of which are hereby incorporated by reference.

### BACKGROUND

### 1. Technical Field

The present disclosure relates to a gas laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 μm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: Japanese Patent No. 4702889
Patent Document 2: U.S. Pat. No. 7,295,591

### SUMMARY

A gas laser device according to an aspect of the present disclosure includes a power source; a main capacitor connected in parallel to the power source; a solid-state switch; a step-up transformer in which a primary side thereof is connected in parallel to the main capacitor via the solid-state switch; a first magnetic pulse compression circuit including a first transfer capacitor to which charges in the main capacitor are transferred and a first magnetic switch, and connected to a secondary side of the step-up transformer; a second magnetic pulse compression circuit including a second transfer capacitor to which charges in the first transfer capacitor are transferred and a second magnetic switch, and connected subsequently to the first magnetic pulse compression circuit; a peaking capacitor which is connected subsequently to the second magnetic pulse compression circuit and to which charges in the second transfer capacitor are transferred; a pair of discharge electrodes configured of a cathode electrode and an anode electrode and connected in parallel to the peaking capacitor; a regenerative transformer in which a primary side thereof is connected in parallel to the main capacitor and a secondary side thereof is connected to the first transfer capacitor, and which is configured to transfer charges generated by the pair of discharge electrodes to the main capacitor after main discharge; and a reset circuit configured to reset the first magnetic switch and the second magnetic switch. Here, potential of the cathode electrode in a period of 0.5 μs to 20 μs both inclusive after the main discharge starts is within a range of −200 V to 200 V both inclusive.

An electronic device manufacturing method according to an aspect of the present disclosure include generating laser light using a gas laser device, outputting the laser light to an exposure apparatus, and exposing a photosensitive substrate to the laser light in the exposure apparatus to manufacture an electronic device. Here, the gas laser device includes a power source; a main capacitor connected in parallel to the power source; a solid-state switch; a step-up transformer in which a primary side thereof is connected in parallel to the main capacitor via the solid-state switch; a first magnetic pulse compression circuit including a first transfer capacitor to which charges in the main capacitor are transferred and a first magnetic switch, and connected to a secondary side of the step-up transformer; a second magnetic pulse compression circuit including a second transfer capacitor to which charges in the first transfer capacitor are transferred and a second magnetic switch, and connected subsequently to the first magnetic pulse compression circuit; a peaking capacitor which is connected subsequently to the second magnetic pulse compression circuit and to which charges in the second transfer capacitor are transferred; a pair of discharge electrodes configured of a cathode electrode and an anode electrode and connected in parallel to the peaking capacitor; a regenerative transformer in which a primary side thereof is connected in parallel to the main capacitor and a secondary side thereof is connected to the first transfer capacitor, and which is configured to transfer charges generated by the pair of discharge electrodes to the main capacitor after main discharge; and a reset circuit configured to reset the first magnetic switch and the second magnetic switch. Potential of the cathode electrode in a period of 0.5 μs to 20 μs both inclusive after the main discharge starts is within a range of −200 V to 200 V both inclusive.

### BRIEF DESCRIPTION OF THE DRAWINGS

Embodiments of the present disclosure will be described below merely as examples with reference to the accompanying drawings.

FIG. 1 is a side view schematically showing the configuration of a gas laser device according to a comparative example.

FIG. 2 is a sectional view schematically showing the configuration of the gas laser device according to the comparative example.

FIG. 3 is a circuit diagram showing the configuration of a pulse power module according to the comparative example.

FIG. 4 is a diagram showing the configuration of a saturable reactor configuring a general magnetic switch.

FIG. 5 is a graph showing a magnetization curve of a core of the saturable reactor.

FIG. 6 is a graph showing an example of a voltage change in each capacitor during magnetic pulse compression operation and regenerative operation.

FIG. 7 is a graph showing an example of a potential change of a cathode electrode after main discharge in the gas laser device according to the comparative example.

FIG. 8 is a graph showing the calculation result of the relationship between a capacitance of a first transfer capacitor and a residual voltage in the first transfer capacitor.

FIG. 9 is a graph showing an example of a change in the voltage in the first transfer capacitor with respect to elapsed time from the start of the main discharge.

FIG. 10 is a graph showing an example of a potential change of the cathode electrode after the main discharge in the gas laser device according to an embodiment.

FIG. 11 is a diagram schematically showing a configuration example of an exposure apparatus.

### DESCRIPTION OF EMBODIMENTS

### <Contents>

1. Comparative example
   1.1 Overview of gas laser device
      1.1.1 Configuration
      1.1.2 Operation
   1.2 Pulse power module
      1.2.1 Configuration
      1.2.2 Magnetic switch
      1.2.3 Operation
      1.2.4 Adjustment of pulse power module
   1.3 Problem
      1.3.1 First peak
      1.3.2 Second peak
      1.3.3 Third peak
2. Embodiment
   2.1 Configuration and operation
   2.2 Adjustment of pulse power module
      2.2.1 First peak
      2.2.2 Second peak
      2.2.3 Third peak
   2.3 Effect
3. Electronic device manufacturing method

Hereinafter, an embodiment of the present disclosure will be described in detail with reference to the drawings. The embodiment described below show some examples of the present disclosure and do not limit the contents of the present disclosure. Also, all configurations and operation described in the embodiment are not necessarily essential as configurations and operation of the present disclosure. Here, the same components are denoted by the same reference numeral, and duplicate description thereof is omitted.

### 1. Comparative Example

First, a comparative example of the present disclosure will be described. The comparative example of the present disclosure is an example recognized by the applicant as known only by the applicant, and is not a publicly known example admitted by the applicant.

### 1.1 Overview of Gas Laser Device

### 1.1.1 Configuration

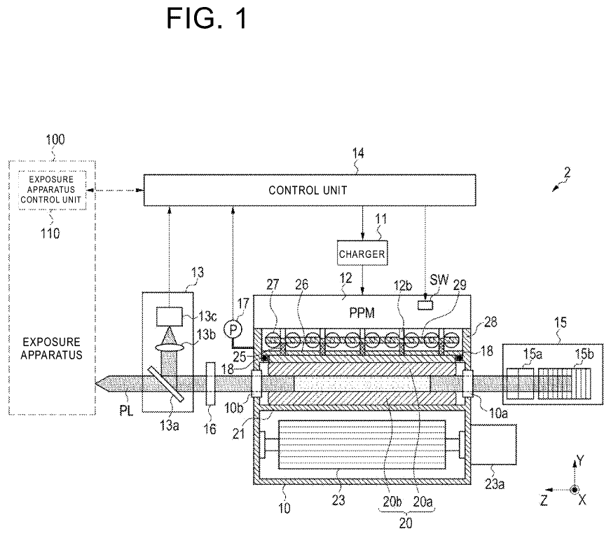

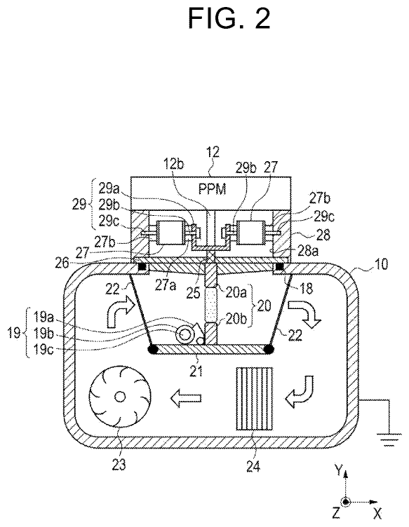

The configuration of a gas laser device 2 according to the comparative example will be described using FIGS. 1 and 2. FIG. 1 schematically shows the configuration of the gas laser device 2. FIG. 2 is a sectional view of the gas laser device 2 shown in FIG. 1 viewed from a Z direction. The gas laser device 2 is a discharge-excitation-type gas laser device, and is, for example, an excimer laser device.

In FIG. 1, the travel direction of pulse laser light PL output from the gas laser device 2 is defined as the Z direction. A discharge direction to be described later is defined as a Y direction. A direction orthogonal to the Z direction and the Y direction is defined as an X direction.

In FIG. 1, the gas laser device 2 includes a laser chamber 10, a charger 11, a pulse power module (PPM) 12, a pulse energy measurement unit 13, a control unit 14, a pressure sensor 17, and a laser resonator. The laser resonator is configured of a line narrowing module 15 and an output coupling mirror (output coupler: OC) 16. Here, the charger 11 is an example of the “power source” according to the technology of the present disclosure.

The laser chamber 10 is, for example, a metal container made of aluminum metal plated with nickel on the surface thereof. In the laser chamber 10, a pair of discharge electrodes 20, a ground plate 21, wirings 22, a fan 23, a heat exchanger 24, and a preionization discharge unit 19 are provided. As shown in FIG. 2, the preionization discharge unit 19 includes a preionization outer electrode 19a, a dielectric pipe 19b, and a preionization inner electrode 19c.

A laser gas as a laser medium is enclosed in the laser chamber 10. The laser gas includes, for example, argon, krypton, xenon, or the like as a rare gas, neon, helium, or the like as a buffer gas, and chlorine, fluorine, or the like as a halogen gas.

Further, an opening is formed in the laser chamber 10. An electrically insulating plate 26 is provided via an O-ring 18 serving as a sealing member so as to block the opening. A plurality of feedthroughs 25 are embedded in the electrically insulating plate 26. A plurality of peaking capacitors 27 and a holder 28 for holding them are arranged on the electrically insulating plate 26. The PPM 12 is arranged on the holder 28. The laser chamber 10 and the holder 28 are grounded.

The pair of discharge electrodes 20 includes a cathode electrode 20a and an anode electrode 20b. The cathode electrode 20a and the anode electrode 20b are arranged in the laser chamber 10 so that discharge surfaces of the both face each other. The space between the discharge surface of the cathode electrode 20a and the discharge surface of the anode electrode 20b is referred to as a discharge space. The cathode electrode 20a is supported by the electrically insulating plate 26 on a surface opposite to the discharge surface. The anode electrode 20b is supported by the ground plate 21 on a surface opposite to the discharge surface.

The feedthroughs 25 are connected to the cathode electrode 20a. Further, as shown in FIG. 2, the feedthroughs 25 are connected to the peaking capacitors 27 held by the holder 28 via a connection portion 29. The connection portion 29 is a member for connecting the peaking capacitors 27 to other components.

A wall 28a defining the internal space of the holder 28 is made of a metal material such as aluminum metal. The plurality of peaking capacitors 27, the connection portion 29, and high voltage terminals 12b of the PPM 12 are arranged in the holder 28. The peaking capacitor 27 is a capacitor that supplies an electric energy received from the PPM 12 and stored therein to the pair of discharge electrodes 20. The peaking capacitor 27 is, for example, a ceramic capacitor in which a dielectric material is formed of strontium titanate.

The peaking capacitors 27 are arranged in a matrix, two pieces in the X direction and plural pieces in the Z direction. The plurality of peaking capacitors 27 are connected in parallel via the connection portion 29. For each of the peaking capacitors 27, one electrode 27a is connected to the high voltage terminal 12b and the feedthrough 25 via the connection portion 29, and the other electrode 27b is connected to the wall 28a of the holder 28 via the connection portion 29.

The connection portion 29 includes a connection plate 29a and connection terminals 29b, 29c. The connection plate 29a is configured by a conductive plate having a U-shaped cross section, and is connected to the high voltage terminal 12b and the feedthrough 25.

The ground plate 21 is connected to the laser chamber 10 via the wirings 22. The laser chamber 10 is grounded. The ground plate 21 is grounded via the wirings 22. An end part of the ground plate 21 in the Z direction is fixed to the laser chamber 10.

The fan 23 is a cross flow fan for circulating the laser gas in the laser chamber 10, and is arranged on the opposite side of the discharge space with respect to the ground plate 21. A motor 23a for rotationally driving the fan 23 is connected to the laser chamber 10.

The laser gas blown out from the fan 23 flows into the discharge space. The flow direction of the laser gas flowing into the discharge space is substantially parallel to the X direction. The laser gas flowing out from the discharge space can be sucked into the fan 23 via the heat exchanger 24. The heat exchanger 24 exchanges heat between a cooling medium supplied to the inside of the heat exchanger 24 and the laser gas.

At end parts of the laser chamber 10, windows 10a, 10b for outputting light generated in the laser chamber 10 to the outside is provided. The laser chamber 10 is arranged such that the optical path of the optical resonator passes through the discharge space and the windows 10a, 10b.

The line narrowing module 15 includes a prism 15a and a grating 15b. The prism 15a transmits the light output from the laser chamber 10 through the window 10a toward the grating 15b while expanding the beam width of the light.

The grating 15b is arranged in the Littrow arrangement in which the incident angle and the diffraction angle are the same. The grating 15b is a wavelength selection element that selectively extracts light in the vicinity of a particular wavelength in accordance with the diffraction angle. The spectral width of the light returning from the grating 15b to the laser chamber 10 via the prism 15a is narrowed.

The output coupling mirror 16 transmits a part of the light output from the laser chamber 10 through the window 10b, and reflects the other part back into the laser chamber 10. The surface of the output coupling mirror 16 is coated with a partial reflection film.

Light output from the laser chamber 10 reciprocates between the line narrowing module 15 and the output coupling mirror 16, and is amplified each time the light passes through the discharge space. A part of the amplified light is output as the pulse laser light PL via the output coupling mirror 16. The pulse laser light PL is an example of the “laser light” according to the technology of the present disclosure.

The pulse energy measurement unit 13 is arranged on the optical path of the pulse laser light PL output via the output coupling mirror 16. The pulse energy measurement unit 13 includes a beam splitter 13a, a light concentrating optical system 13b, and an optical sensor 13c.

The beam splitter 13a transmits the pulse laser light PL with a high transmittance and reflects a part of the pulse laser light PL toward the light concentrating optical system 13b. The light concentrating optical system 13b concentrates the light reflected by the beam splitter 13a on a light receiving surface of the optical sensor 13c. The optical sensor 13c measures the pulse energy of the light concentrated on the light receiving surface, and outputs the measurement value to the control unit 14.

The pressure sensor 17 detects the gas pressure in the laser chamber 10, and outputs the detection value to the control unit 14. The control unit 14 determines the gas pressure of the laser gas in the laser chamber 10 based on the detection value of the gas pressure and the charge voltage of the charger 11.

The charger 11 is a high voltage power source that supplies a constant charge voltage to a later-described main capacitor C0 included in the PPM 12. The PPM 12 includes a solid-state switch SW controlled by the control unit 14. The solid-state switch SW is a semiconductor switching element configured by an insulated gate bipolar transistor (IGBT). When the solid-state switch SW is turned ON from OFF, the PPM 12 generates a high voltage pulse from the electric energy held in the main capacitor C0 and applies the high voltage pulse to the pair of discharge electrodes 20.

The control unit 14 is a processor that transmits and receives various signals to and from an exposure apparatus control unit 110 provided in the exposure apparatus 100. For example, the exposure apparatus control unit 110 transmits, to the control unit 14, the target pulse energy of the pulse laser light PL to be output to the exposure apparatus 100, a signal related to the target oscillation timing, and the like.

The control unit 14 generally controls the operation of each component of the gas laser device 2 based on various signals transmitted from the exposure apparatus control unit 110, the measurement value of the pulse energy, the detection value of the gas pressure, and the like.

### 1.1.2 Operation

The control unit 14 controls a laser gas supply unit (not shown) so that the laser gas is supplied into the laser chamber 10.

The control unit 14 drives the motor 23a to rotate the fan 23. Thus, the laser gas circulates in the laser chamber 10.

The control unit 14 receives signals related to a target pulse energy Et and the target oscillation timing transmitted from the exposure apparatus control unit 110.

The control unit 14 sets a charge voltage Vhv corresponding to the target pulse energy Et in the charger 11. The control unit 14 stores the value of the charge voltage Vhv set in the charger 11. The control unit 14 operates the solid-state switch SW of the PPM 12 in synchronization with the target oscillation timing.

When the solid-state switch SW of the PPM 12 is turned ON from OFF, a voltage may be applied between the preionization inner electrode 19c and the preionization outer electrode 19a of the preionization discharge unit 19. As a result, corona discharge occurs in the preionization discharge unit 19, and ultraviolet (UV) light is generated. When the laser gas in the discharge space is irradiated with the UV light, the laser gas is preionized. Then, a voltage is applied to the pair of discharge electrodes 20.

Thereafter, main discharge occurs in the discharge space. When the discharge direction of the main discharge is defined as a direction in which electrons flow, the discharge direction is the direction from the cathode electrode 20a toward the anode electrode 20b. When the main discharge occurs, the laser gas in the discharge space is excited to emit light.

Light emitted from the laser gas is reflected by the line narrowing module 15 and the output coupling mirror 16 and reciprocates in the laser resonator, thereby performing laser oscillation. The light line-narrowed by the line narrowing module 15 is output from the output coupling mirror 16 as the pulse laser light PL.

A part of the pulse laser light PL output from the output coupling mirror 16 enters the pulse energy measurement unit 13. The pulse energy measurement unit 13 measures a pulse energy E of the entering pulse laser light PL, and outputs the measurement value to the control unit 14.

The control unit 14 stores the measurement value of the pulse energy E measured by the pulse energy measurement unit 13. The control unit 14 calculates a difference ΔE between the measurement value of the pulse energy E and the target pulse energy Et. The control unit 14 performs feedback control on the charge voltage Vhv based on the difference ΔE so that the measurement value of the pulse energy E becomes the target pulse energy Et.

### 1.2 Pulse Power Module

### 1.2.1 Configuration

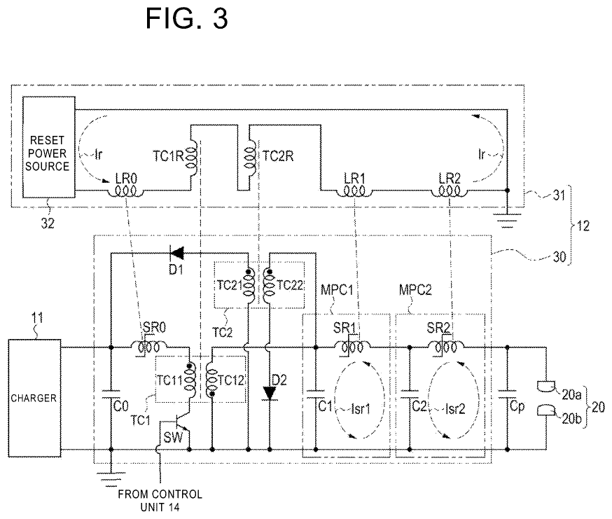

The schematic configuration of the PPM 12 according to the comparative example will be described using FIG. 3. The PPM 12 includes a power source circuit 30 as a high voltage generation device and a reset circuit 31. In FIG. 3, the above-described plurality of peaking capacitors 27 connected in parallel are represented as one peaking capacitor Cp.

The power source circuit 30 is connected between the charger 11 and the peaking capacitor Cp. The power source circuit 30 includes the main capacitor C0, the solid-state switch SW, a step-up transformer TC1, a first magnetic pulse compression circuit MPC1, a second magnetic pulse compression circuit MPC2, and a regenerative transformer TC2. The solid-state switch SW is controlled by the control unit 14 described above.

The main capacitor C0 is connected in parallel to the charger 11. A primary side of the step-up transformer TC1 is connected in parallel to the main capacitor C0 via the solid-state switch SW. Specifically, the step-up transformer TC1 includes a primary winding TC11 and a secondary winding TC12. The primary winding TC11 is connected in parallel to the main capacitor C0 via the solid-state switch SW and a magnetic switch SR0.

The first magnetic pulse compression circuit MPC1 is connected in parallel to a secondary side of the step-up transformer TC1. Specifically, the first magnetic pulse compression circuit MPC1 includes a first transfer capacitor C1 and a first magnetic switch SR1. The first transfer capacitor C1 is connected in parallel to the secondary winding TC12 of the step-up transformer TC1, and charges in the main capacitor C0 charged by the charger 11 are transferred thereto.

The second magnetic pulse compression circuit MPC2 is connected subsequently to the first magnetic pulse compression circuit MPC1. Specifically, the second magnetic pulse compression circuit MPC2 includes a second transfer capacitor C2 and a second magnetic switch SR2. The second transfer capacitor C2 is connected in parallel to the first transfer capacitor C1 via the first magnetic switch SR1, and charges in the first transfer capacitor C1 are transferred thereto.

The peaking capacitor Cp is connected in parallel to the second transfer capacitor C2 via the second magnetic switch SR2. Charges in the second transfer capacitor C2 are transferred to the peaking capacitor Cp. The pair of discharge electrodes 20 are connected in parallel to the peaking capacitor Cp.

After the main discharge occurs between the pair of discharge electrodes 20, charges may travel in the reverse direction between the peaking capacitor Cp and the main capacitor C0 and then travel in the forward direction, which may adversely affect the main discharge. Therefore, the regenerative transformer TC2 and diodes D1, D2 configure a regenerative circuit for storing, in the main capacitor C0, the charges transferred from the peaking capacitor Cp to the main capacitor C0 after the main discharge and regenerating the stored charges as a part of the subsequent charge energy.

The regenerative transformer TC2 includes a primary winding TC21 and a secondary winding TC22. The primary winding TC21 is connected in parallel to the main capacitor C0 via the diode D1. The secondary winding TC22 is connected in parallel to the first transfer capacitor C1 via the diode D2.

In FIG. 3, dots shown in the step-up transformer TC1 and the regenerative transformer TC2 represent the polarity of the windings. In the step-up transformer TC1, the primary winding TC11 and the secondary winding TC12 have polarities reverse to each other. Therefore, the step-up transformer TC1 transfers the voltage charged in the main capacitor C0 to the first transfer capacitor C1 while changing the polarity, that is, in a reverse phase. In the regenerative transformer TC2, the primary winding TC21 and the secondary winding TC22 have polarities identical to each other. Therefore, the regenerative transformer TC2 transfers the voltage charged in the first transfer capacitor C1 to the main capacitor C0 without changing the polarity, that is, in the same phase.

The reset circuit 31 includes a reset power source 32, a magnetic-switch-reset winding LR0, a first-magnetic-switch-reset winding LR1, a second-magnetic-switch-reset winding LR2, a step-up-transformer-reset winding TC1R, and a regenerative-transformer-reset winding TC2R. The magnetic-switch-reset winding LR0, the first-magnetic-switch-reset winding LR1, the second-magnetic-switch-reset winding LR2, the step-up-transformer-reset winding TC1R, and the regenerative-transformer-reset winding TC2R are connected in series and are connected to the reset power source 32. The reset power source 32 is a constant current source.

The magnetic-switch-reset winding LR0 is wound around a core of the magnetic switch SR0, and resets an operation point of the core in response to energization. The first-magnetic-switch-reset winding LR1 is wound around a core of the first magnetic switch SR1, and resets an operation point of the core in response to energization. The second-magnetic-switch-reset winding LR2 is wound around a core of the second magnetic switch SR2, and resets an operation point of the core in response to energization. The step-up-transformer-reset winding TC1R is wound around a core of the step-up transformer TC1, and resets an operation point of the core in response to energization. The regenerative-transformer-reset winding TC2R is wound around a core of the regenerative transformer TC2, and resets an operation point of the core in response to energization.

The reset circuit 31 is magnetically coupled to magnetic switches SR0, SR1, SR2 included in the power source circuit 30. Each of the magnetic switches SR0, SR1, SR2 is configured by a saturable reactor. The magnetic switch SR0 reduces the switching loss that occurs in the solid-state switch SW.

The elements of the first magnetic pulse compression circuit MPC1 and the second magnetic pulse compression circuit MPC2 are designed such that the pulse width of the current pulse is sequentially narrowed in order to generate large discharge with the pair of discharge electrodes 20. The first magnetic pulse compression circuit MPC1 compresses the pulse width of the current pulse when charges are transferred from the first transfer capacitor C1 to the second transfer capacitor C2. The second magnetic pulse compression circuit MPC2 compresses the pulse width of the current pulse when charges are transferred from the second transfer capacitor C2 to the peeking capacitor Cp.

### 1.2.2 Magnetic Switch

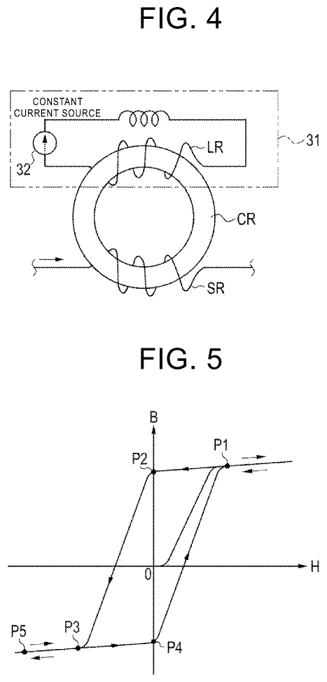

Next, details of the configuration and operation of the magnetic switches SR0, SR1, SR2 included in the power source circuit 30 will be described. FIG. 4 shows the configuration of a saturable reactor configuring a general magnetic switch. FIG. 5 shows a magnetization curve of a core of the saturable reactor. As shown in FIG. 4, a main winding SR and a reset winding LR are wound around a core CR. The reset winding LR is connected to the reset circuit 31.

When a direct current flows through the reset winding LR at the time when the operation point of the core CR is at the “0” point in FIG. 5, the operation point of the core CR moves to P5. When an excitation current flows through the main winding SR, magnetic field strength H increases. As a result, the operation point of the core CR moves from P5 toward P1 via P4.

When the operation point of the core CR reaches P1, a magnetic flux density B in the core CR becomes equal to or higher than a saturation magnetic flux density, and the saturable reactor is saturated. At this time, the inductance of the saturable reactor rapidly decreases, and the main winding SR becomes conductive. When the saturable reactor is saturated, the operation point of the core CR is located at a point where the magnetic field strength His much greater than that at P1, but the operation point moves from P1 toward P2 as the current flowing through the main winding SR decreases. At this time, since the inductance of the saturable reactor rapidly increases, the current flowing through the main winding SR rapidly decreases. When the current flowing through the main winding SR becomes 0, the operation point of the core CR stops at P2, and the magnetic flux remains in the core CR.

When the excitation current flows through the main winding SR again in a state that the operation point of the core CR is at P2, the operation point of the core CR moves from P2 toward P1. The amount of change in the magnetic flux density B at this time is smaller than the amount of change when moving from P5 toward P1 via P4. Therefore, the inductance of the saturable reactor at the time of non-saturation does not become sufficiently large, and magnetic pulse compression operation can be hardly performed. To perform the magnetic pulse compression operation, magnetic resetting must be performed so as to return the operation point of the core CR from P2 to P5 via P3. Therefore, a direct current in a reverse direction with respect to the main winding SR is caused to flow through the reset winding LR as a reset current. The operation point of the core CR is returned to P5 after the current flowing through the main winding SR reaches 0.

### 1.2.3 Operation

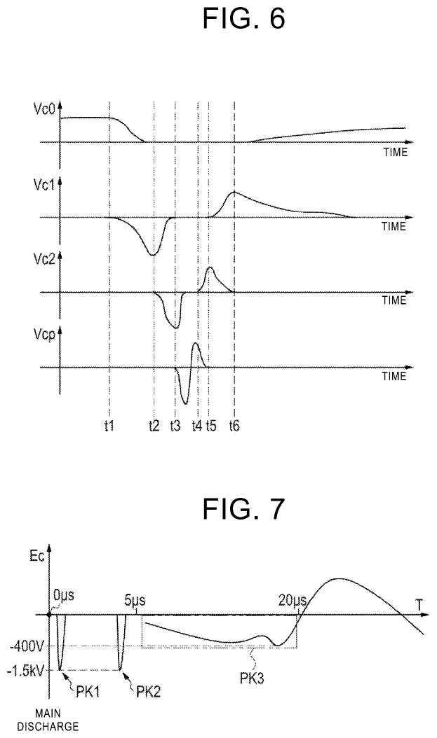

Operation of the PPM 12 according to the comparative example will be described using FIG. 6. First, the main capacitor C0 is charged by the charger 11 while the solid-state switch SW is kept OFF by the control unit 14. Here, a voltage Vc0 in the charged main capacitor C0 is positive.

When the solid-state switch SW is turned ON from OFF by the control unit 14, the voltage Vc0 in the main capacitor C0 is applied to the magnetic switch SR0. When the time integration value of the voltage Vc0 in the main capacitor C0 reaches a limit value determined by the characteristic of the magnetic switch SR0, the magnetic switch SR0 is saturated and the inductance thereof decreases. Time t1 in FIG. 6 indicates the timing at which the inductance of the magnetic switch SR0 starts to decrease.

After time t1, a current flows through a loop of the main capacitor C0, the magnetic switch SR0, the primary winding TC11 of the step-up transformer TC1, and the solid-state switch SW. At the same time, a current also flows through a loop of the secondary winding TC12 of the step-up transformer TC1 and the first transfer capacitor C1. As a result, charges stored in the main capacitor C0 are transferred to the first transfer capacitor C1, and the first transfer capacitor C1 is charged negatively.

When the time integration value of a voltage Vc1 in the first transfer capacitor C1 reaches a limit value determined by the characteristic of the first magnetic switch SR1, the first magnetic switch SR1 is saturated and the inductance thereof decreases. Time t2 in FIG. 6 indicates the timing at which the inductance of the first magnetic switch SR1 starts to decrease. After time t2, a current flows through a loop of the first transfer capacitor C1, the second transfer capacitor C2, and the first magnetic switch SR1. As a result, charges stored in the first transfer capacitor C1 are transferred to the second transfer capacitor C2, and the second transfer capacitor C2 is charged negatively.

When the time integration value of a voltage Vc2 in the second transfer capacitor C2 reaches a limit value determined by the characteristic of the second magnetic switch SR2, the second magnetic switch SR2 is saturated and the inductance thereof rapidly decreases. Time t3 in FIG. 6 indicates the timing at which the inductance of the second magnetic switch SR2 starts to decrease.

After time t3, a current flows through a loop of the second transfer capacitor C2, the peaking capacitor Cp, and the second magnetic switch SR2. As a result, charges stored in the second transfer capacitor C2 are transferred to the peaking capacitor Cp, and the peaking capacitor Cp is charged negatively.

When a voltage Vcp of the peaking capacitor Cp reaches a breakdown voltage, breakdown occurs at the laser gas between the pair of discharge electrodes 20, and the main discharge starts. When the laser medium is excited by the main discharge, light is generated.

After the main discharge, a reverse voltage is applied to the peaking capacitor Cp due to residual charges of the main discharge and the like. That is, the peaking capacitor Cp is charged positively. Time t4 in FIG. 6 indicates the timing at which the peaking capacitor Cp is charged positively.

After time t4, charges are transferred from the peaking capacitor Cp to the second transfer capacitor C2, and charges are transferred from the second transfer capacitor C2 to the first transfer capacitor C1. Similarly to the peaking capacitor Cp, each of the second transfer capacitor C2 and the first transfer capacitor C1 is applied with a voltage having a reverse polarity with respect to the charge voltage during the magnetic pulse compression operation. That is, the second transfer capacitor C2 and the first transfer capacitor C1 are charged positively. Time t5 in FIG. 6 indicates the timing at which the second transfer capacitor C2 is charged positively. Time t6 in FIG. 6 indicates the timing at which the first transfer capacitor C1 is charged positively.

Since the solid-state switch SW is kept OFF during regenerative operation, the transferring of charges from the first transfer capacitor C1 to the main capacitor C0 is performed via the regenerative transformer TC2. As a result, the main capacitor C0 is charged to the same polarity as the voltage charged by the charger 11, that is, positively. At this time, the solid-state switch SW is turned OFF, and since the diodes D1, D2 are connected with polarities reverse to each other, charges are stored in the main capacitor C0 until the solid-state switch SW is turned ON by the control unit 14.

When the regenerative operation is completed, the voltages Vc1, Vc2, Vcp are approximately 0. However, since a current flows through the reset circuit 31 even after the main capacitor C0 is charged by the regenerative operation, the voltages Vc1, Vc2, Vcp change. The voltage Vcp and the voltage Vc2 decrease over time, and increase in synchronization with the timing at which the core of the second magnetic switch SR2 is reset. On the other hand, the voltage Vc1 increases over time and then decreases.

Then, the voltages Vc1, Vc2, Vcp increase in synchronization with the timing at which the core of the first magnetic switch SR1 is reset, and decrease at the timing at which the core of the step-up transformer TC1 is reset, and eventually converges to 0.

When the repetition frequency of the pulse laser light PL is less than about 4 kHz, since the pulse interval is more than about 250 μs, the voltages Vc1, Vc2, Vcp converge to 0 in a period between the occurrence of the main discharge and subsequent magnetic pulse compression operation.

However, when the repetition frequency of the pulse laser light PL is more than about 6 kHz, since the pulse interval is less than about 166 μs, subsequent magnetic pulse compression operation starts before the voltages Vc1, Vc2, Vcp converge to 0. This is because each of the voltages Vc1, Vc2, Vcp has a high peek value on the positive side and requires time to converge to 0. When charging is started by the magnetic pulse compression operation while a voltage is present in the peaking capacitor Cp, the main discharge may be adversely affected.

### 1.2.4 Adjustment of Pulse Power Module

In order to suppress the adverse effect on the main discharge, it is preferable to reduce the peak value of the voltage Vcp caused due to the reset current after the main discharge. In the comparative example, an upper limit value VL is set at elapsed time T from the main discharge, and the PPM 12 is adjusted so that the voltage Vcp does not exceed the upper limit value VL. For example, VL=0V is set for a period of 1 μs≤T<20 μs, VL=300V is set for a period of 20 μs≤T<30 μs, and VL=500V is set for a period of 30 μs≤T.

Specifically, in the comparative example, the PPM 12 is adjusted in advance so as to satisfy a first adjustment condition and a second adjustment condition in order to suppress the voltage Vcp of the peaking capacitor Cp to be equal to or lower than the upper limit value VL. The first adjustment condition is a condition for causing the voltage Vc1 after the regenerative operation is completed to be negative. The second adjustment condition is a condition for suppressing an increase rate of the voltage Vcp after the regenerative operation is completed.

The parameters related to the first adjustment condition and the second adjustment condition are defined as follows.
C_{C0}: Capacitance of the main capacitor C0
C_{C1}: Capacitance of the first transfer capacitor C1
C_{C2}: Capacitance of the second transfer capacitor C2
C_{Cp}: Capacitance of the peaking capacitor Cp
N_{TC11}: Number of turns of the primary winding TC11 of the step-up transformer TC1
N_{TC12}: Number of turns of the secondary winding TC12 of the step-up transformer TC1
N_{TC21}: Number of turns of the primary winding TC21 of the regenerative transformer TC2
N_{TC22}: Number of turns of the secondary winding TC22 of the regenerative transformer TC2
I_{TC1R}: Reset current flowing through the step-up-transformer-reset winding TC1R
I_{TC2R}: Reset current flowing through the regenerative-transformer-reset winding TC2R

The first adjustment condition is defined by the following expressions (1) and (2).

$$[ Expression 1 ]$$

$$\frac{{N}_{TC 12}}{{N}_{TC 11}} > \sqrt{\frac{{C}_{C 0}}{{C}_{C 1}}} \qquad ( 1 )$$

$$[ Expression 2 ]$$

$$\frac{{N}_{TC 22}}{{N}_{TC 21}} < \sqrt{\frac{{C}_{C 0}}{{C}_{C 1}}} \qquad ( 2 )$$

The second adjustment condition is defined by the following expressions (3) and (4). Here, K is a constant representing a predetermined voltage increase rate.

$$[ Expression 3 ]$$

$$( {I}_{TC 1 R} \times \frac{{N}_{TC 1 R}}{{N}_{TC 12}} - {I}_{TC 2 R} \times \frac{{N}_{TC 2 R}}{{N}_{TC 22}} ) / ( {C}_{C 1} + {C}_{C 2} + {C}_{Cp} ) < K \qquad ( 3 )$$

$$[ Expression 4 ]$$

$${I}_{TC 1 R} \times \frac{{N}_{TC 1 R}}{{N}_{TC 12}} - {I}_{TC 2 R} \times \frac{{N}_{TC 2 R}}{{N}_{TC 22}} > 0 \qquad ( 4 )$$

Further, the capacitances C_{C1}, C_{C2}, C_{Cp} satisfy the following expression (5).

$$[ Expression 5 ]$$

$${C}_{Cp} < {C}_{C 1} = {C}_{C 2} \qquad ( 5 )$$

### 1.3 Problem

The applicant has confirmed that, when the gas laser device 2 according to the comparative example in which the PPM 12 is adjusted as described above is discharged, a negative kickback waveform is generated between the pair of discharge electrodes 20 after the main discharge, and the intensity of the arc discharge increases. When the intensity of the arc discharge increases, the amount of wear of the pair of discharge electrodes 20 increases, and the lifetime thereof is shortened. The energy stability of the laser output is also reduced.

Further, the applicant has confirmed that the intensity of the arc discharge increases when CM1200hc-66X (hereinafter referred to as “66X”) or 5SNA_1000N330300 (hereinafter referred to as “ABB”) is used as the solid-state switch SW than when CM1200HC-66H (hereinafter referred to as “66H”) is used. Here, 66H and 66X are IGBT modules manufactured by Mitsubishi Electric Corporation, and ABB is an IGBT module manufactured by ABB Corporation.

It is considered that the increase in the intensity of the arc discharge is caused by occurrence of a first peak PK1, a second peak PK2, and a third peak PK3 in potential Ec of the cathode electrode 20a after the main discharge, as shown in FIG. 7. Assuming that the elapsed time from the main discharge is T, the first peak PK1 and the second peak PK2 occur in a period of 0.5 μs<T<5 μs. The third peak PK3 occurs in the period of 5 μs<T<20 μs. The first peak PK1 and the second peak PK2 are at negative potential of about −1.5 kV. The third peak PK3 is at negative potential of about −400 V.

### 1.3.1 First Peak

Occurrence of the first peak PK1 is caused by a voltage remaining in the first transfer capacitor C1 after the magnetic pulse compression operation. Specifically, the cause is that a voltage remains in the first transfer capacitor C1 when a voltage is transferred from the first transfer capacitor C1 to the second transfer capacitor C2 for the main discharge. The cause of a voltage remaining in the first transfer capacitor C1 is that the transfer efficiency is not 100% due to loss of the first magnetic switch SR1 and that C_{C1}-C_{C2} is set as in the above expression (5). After the main discharge, the residual voltage in the first transfer capacitor C1 moves to the pair of discharge electrodes 20 via the first transfer capacitor C1, the second transfer capacitor C2, and the peaking capacitor Cp, thereby causing the first peak PK1 to occur.

### 1.3.2 Second Peak

Occurrence of the second peak PK2 is caused due to that the solid-state switch SW is not completely turned OFF during the regenerative operation, so that the first transfer capacitor C1 is charged and a non-regenerative voltage occurs. The non-regenerative voltage means a voltage that remains in the first transfer capacitor C1 without being transferred to the main capacitor C0 during the regenerative operation. Specifically, it is preferable that the solid-state switch SW is completely turned OFF at time t5 shown in FIG. 6, but the solid-state switch SW is not completely turned OFF at time t5 due to the turn-off time of the solid-state switch SW, so that the non-regenerative voltage occurs.

Since 66X and ABB each have a short turn-on time and a long turn-off time compared to 66H, usage of 66X or ABB as the solid-state switch SW increases the non-regenerative voltage in the first transfer capacitor C1.

### 1.3.3 Third Peak

Occurrence of the third peak PK3 is caused by a current generated in the first magnetic pulse compression circuit MPC1 and the second magnetic pulse compression circuit MPC2 due to the reset current for resetting the first magnetic switch SR1 and the second magnetic switch SR2. That is, occurrence of the third peak PK3 is caused by energy injection from the reset circuit 31 into the pair of discharge electrodes 20.

In FIG. 3, Ir represents the reset current flowing through the reset circuit 31 when the first magnetic switch SR1 and the second magnetic switch SR2 are to be reset. Isr1 represents a current generated in the first magnetic pulse compression circuit MPC1 at the time of reset. Isr2 represents a current generated in the second magnetic pulse compression circuit MPC2 at the time of reset. The currents Isr1, Isr2 are currents for returning the first magnetic switch SR1 and the second magnetic switch SR2 to the initial state, respectively.

### 2. Embodiment

### 2.1 Configuration and Operation

The gas laser device 2 according to an embodiment of the present invention has a configuration similar to that of the gas laser device 2 according to the comparative example except that the adjustment conditions of the PPM 12 are different. Further, operation of the gas laser device 2 according to the present embodiment is similar to that of the gas laser device 2 according to the comparative example.

### 2.2 Adjustment of Pulse Power Module

In the present embodiment, the first peak PK1, the second peak PK2, and the third peak PK3 occurring in the potential Ec of the cathode electrode 20a after the main discharge are suppressed by changing the adjustment conditions of the PPM 12 according to the comparative example. Hereinafter, only differences with respect to the comparative example will be described.

2.2.1 First Peak

In the present embodiment, the capacitances C_{C1}, C_{C2}, C_{Cp} are adjusted so as to satisfy the relationship of the following expression (6) in order to suppress the residual voltage in the first transfer capacitor C1, which is the cause of occurrence of the first peak PK1. That is, the capacitances C_{C1}, C_{C2}, C_{Cp} are adjusted using the following expression (6) instead of the above expression (5). Here, suppressing the residual voltage means to bring the residual voltage close to 0.

$$[ Expression 6 ]$$

$${C}_{Cp} < {C}_{C 1} < {C}_{C 2} \qquad ( 6 )$$

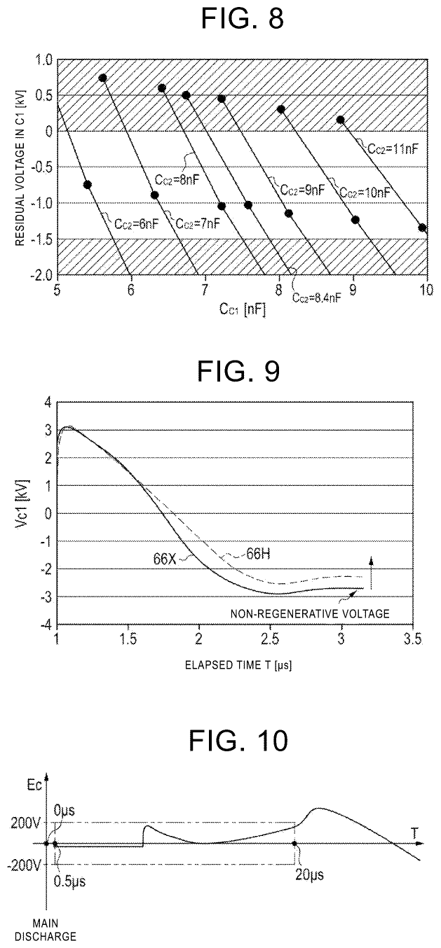

FIG. 8 shows the relationship between the capacitance C_{C1} of the first transfer capacitor C1 and the residual voltage in the first transfer capacitor C1. Specifically, FIG. 8 shows the result in which the capacitance C_{C1} is changed in the range from 5 nF to 10 nF using the capacitance C_{C2} of the second transfer capacitor C2 as a parameter.

It was confirmed that the first peak PK1 was suppressed by adjusting the capacitance C_{C1} so as to satisfy the following expression (7) in a state in which the above expression (6) is satisfied and the charger 11 is set to the maximum output.

$$[ Expression 7 ]$$

$$- 1.5 kV < Vrd < 0 V \qquad ( 7 )$$

Here, Vrd represents the residual voltage in the first transfer capacitor C1.

### 2.2.2 Second Peak

In the present embodiment, in order to suppress the non-regenerative voltage, which is the cause of occurrence of the second peak PK2, the ratio between the numbers of turns of the primary winding TC21 and the secondary winding TC22 of the regenerative transformer TC2 is adjusted so as to satisfy the following expression (8) instead of the above expression (2). Here, suppressing the non-regenerative voltage means to bring the non-regenerative voltage close to 0.

$$[ Expression 8 ]$$

$$\frac{{N}_{TC 22}}{{N}_{TC 21}} > \sqrt{\frac{{C}_{C 0}}{{C}_{C 1}}} \qquad ( 8 )$$

As a result, the relationship between the voltage on the primary side and the voltage on the secondary side of the regenerative transformer TC2 is changed, and the first transfer capacitor C1 is less likely to be charged during the regenerative operation.

FIG. 9 shows an example of a change in the voltage Vc1 in the first transfer capacitor C1 with respect to the elapsed time T after the main discharge starts. FIG. 9 shows changes in the voltage Vc1 between the case in which 66H is used as the solid-state switch SW and the case in which 66X is used thereas. 66X generates a non-regenerative voltage larger than 66H because the turn-off time is longer than that of 66H and that there is a period not completely turning OFF during the regenerative operation.

By adjusting the regenerative transformer TC2 so as to satisfy the above expression (8), the non-regenerative voltage is suppressed. For example, when 66X is used as the solid-state switch SW, the regenerative transformer TC2 is adjusted so as to satisfy the above expression (8), so that the non-regenerative voltage is suppressed as compared with the case in which 66H is used as the solid-state switch SW and the above expression (8) is not satisfied. Therefore, by adjusting the regenerative transformer TC2 so as to satisfy the above expression (8), the second peak PK2 is suppressed.

### 2.2.3 Third Peak

In the present embodiment, in order to suppress energy injection from the reset circuit 31 to the pair of discharge electrodes 20, which is the cause of occurrence of the third peak PK3, the reset current Ir flowing through the reset circuit 31 is set to be equal to or more than 3 A. Further, the current Isr1 generated in the first magnetic pulse compression circuit MPC1 at the time of reset and the current Isr2 generated in the second magnetic pulse compression circuit MPC2 at the time of reset satisfy the following expression (9).

$$[ Expression 9 ]$$

$$Isr 2 > 2.5 \times Isr 1 \qquad ( 9 )$$

The relationship of the above expression (9) is satisfied by adjusting the ratio between the number of windings of the first magnetic switch SR1 and the number of windings of the second magnetic switch SR2.

By satisfying the relationship of the above expression (9), the reset force of the second magnetic switch SR2 becomes higher than the reset force of the first magnetic switch SR1. Further, by setting the reset current Ir to be equal to or more than 3 A, the reset force of the second magnetic switch SR2 increases. As a result, energy injection from the reset circuit 31 into the pair of discharge electrodes 20 is suppressed, so that the third peak PK3 is suppressed.

### 2.3 Effect

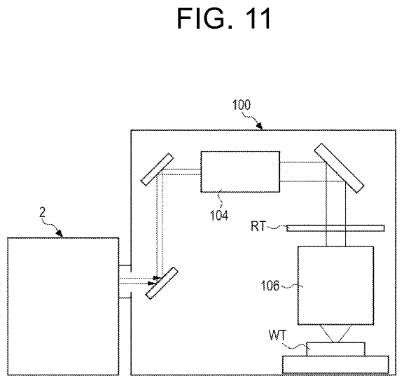

By adjusting the PPM 12 as described above, the first peak PK1, the second peak PK2, and the third peak PK3 are suppressed. As a result, as shown in FIG. 10, the potential Ec of the cathode electrode 20a in a period of 0.5 μs to 20 μs both inclusive after the main discharge starts is within a range of −200 V to 200 V both inclusive. For example, the start of the main discharge is specified as a time point at which a breakdown occurs between the pair of discharge electrodes 20 by a voltage transferred from the main capacitor C0 to the peaking capacitor Cp through the magnetic pulse compression operation.

By suppressing the negative kickback waveform as described above, the arc discharge is suppressed and the lifetime of the pair of discharge electrodes 20 is extended. This also improves the energy stability of the laser output.

### 3. Electronic Device Manufacturing Method

FIG. 11 schematically shows a configuration example of the exposure apparatus 100. The exposure apparatus 100 includes an illumination optical system 104 and a projection optical system 106. For example, the illumination optical system 104 illuminates a reticle pattern of a reticle (not shown) arranged on a reticle stage RT with the pulse laser light PL incident from the gas laser device 2. The projection optical system 106 causes the pulse laser light PL transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 100 synchronously translates the reticle stage RT and the workpiece table WT to expose the workpiece to the pulse laser light PL reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure.

The description above is intended to be illustrative and the present disclosure is not limited thereto. Therefore, it would be obvious to those skilled in the art that various modifications to the embodiments of the present disclosure would be possible without departing from the spirit and the scope of the appended claims.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.”

What is claimed is:

1. A gas laser device comprising:
a power source;
a main capacitor connected in parallel to the power source;
a solid-state switch;
a step-up transformer in which a primary side thereof is connected in parallel to the main capacitor via the solid-state switch;
a first magnetic pulse compression circuit including a first transfer capacitor to which charges in the main capacitor are transferred and a first magnetic switch, and connected to a secondary side of the step-up transformer;
a second magnetic pulse compression circuit including a second transfer capacitor to which charges in the first transfer capacitor are transferred and a second magnetic switch, and connected subsequently to the first magnetic pulse compression circuit;
a peaking capacitor which is connected subsequently to the second magnetic pulse compression circuit and to which charges in the second transfer capacitor are transferred;
a pair of discharge electrodes configured of a cathode electrode and an anode electrode and connected in parallel to the peaking capacitor;
a regenerative transformer in which a primary side thereof is connected in parallel to the main capacitor and a secondary side thereof is connected to the first transfer capacitor, and which is configured to transfer charges generated by the pair of discharge electrodes to the main capacitor after main discharge; and
a reset circuit configured to reset the first magnetic switch and the second magnetic switch,
potential of the cathode electrode in a period of 0.5 μs to 20 μs both inclusive after the main discharge starts being within a range of −200 V to 200 V both inclusive.

2. The gas laser device according to claim 1,
wherein a relationship of C_{Cp}<C_{C1}<C_{C2} is satisfied, where C_{C1} is a capacitance of the first transfer capacitor, C_{C2} is a capacitance of the second transfer capacitor, and C_{Cp} is a capacitance of the peeking capacitor.

3. The gas laser device according to claim 2,
wherein a relationship of 5 nF<C_{C1}<10 nF is satisfied.

4. The gas laser device according to claim 3,
wherein a relationship of −1.5 kV<Vrd<0V is satisfied, where Vrd is a residual voltage remaining in the first transfer capacitor after charges are transferred from the first transfer capacitor to the second transfer capacitor.

5. The gas laser device according to claim 1,
wherein a relationship of N_{TC22}/N_{TC21}>(C_{C0}/C_{C1})^{0.5} is satisfied, where C_{C0} is a capacitance of the main capacitor, C_{C1} is a capacitance of the first transfer capacitor, N_{TC21} is a number of turns of a primary winding of the regenerative transformer, and N_{TC22} is a number of turns of a secondary winding of the regenerative transformer.

6. The gas laser device according to claim 5,
wherein a relationship of N_{TC12}/N_{TC11}>(C_{C0}/C_{C1})^{0.5} is satisfied, where N_{TC11} is a number of turns of a primary winding of the step-up transformer and N_{TC12} is a number of turns of a secondary winding of the step-up transformer.

7. The gas laser device according to claim 1,
wherein a relationship of Isr2>2.5×Isr1 is satisfied, where Isr1 is a current generated in the first magnetic pulse compression circuit at a time of reset and Isr2 is a current generated in the second magnetic pulse compression circuit at the time of reset.

8. The gas laser device according to claim 7,
wherein a reset current flowing through the reset circuit at the time of reset is equal to or more than 3 A.

9. The gas laser device according to claim 1,
wherein relationships of C_{Cp}<C_{C1}<C_{C2}, N_{TC22}/N_{TC21}>(C_{C0}/C_{C1})^{0.5}, and Isr2>2.5×Isr1 are satisfied, where C_{C0} is a capacitance of the main capacitor, C_{C1} is a capacitance of the first transfer capacitor, C_{C2} is a capacitance of the second transfer capacitor, C_{Cp} is a capacitance of the peeking capacitor, N_{TC21} is a number of turns of a primary winding of the regenerative transformer, N_{TC22} is a number of turns of a secondary winding of the regenerative transformer, Isr1 is a current generated in the first magnetic pulse compression circuit at a time of reset, and Isr2 is a current generated in the second magnetic pulse compression circuit at the time of reset.

10. The gas laser device according to claim 1,
wherein the solid-state switch is an insulated gate bipolar transistor.

11. The gas laser device according to claim 1,
wherein, in the step-up transformer, a primary winding and a secondary winding have polarities reverse to each other, and in the regenerative transformer, a primary winding and a secondary winding have polarities identical to each other.

12. An electronic device manufacturing method, comprising:
generating laser light using a gas laser device;
outputting the laser light to an exposure apparatus; and
exposing a photosensitive substrate to the laser light in the exposure apparatus to manufacture an electronic device,
the gas laser device including:
a power source;
a main capacitor connected in parallel to the power source;
a solid-state switch;
a step-up transformer in which a primary side thereof is connected in parallel to the main capacitor via the solid-state switch;
a first magnetic pulse compression circuit including a first transfer capacitor to which charges in the main capacitor are transferred and a first magnetic switch, and connected to a secondary side of the step-up transformer;
a second magnetic pulse compression circuit including a second transfer capacitor to which charges in the first transfer capacitor are transferred and a second magnetic switch, and connected subsequently to the first magnetic pulse compression circuit;
a peaking capacitor which is connected subsequently to the second magnetic pulse compression circuit and to which charges in the second transfer capacitor are transferred;
a pair of discharge electrodes configured of a cathode electrode and an anode electrode and connected in parallel to the peaking capacitor;
a regenerative transformer in which a primary side thereof is connected in parallel to the main capacitor and a secondary side thereof is connected to the first transfer capacitor, and which is configured to transfer charges generated by the pair of discharge electrodes to the main capacitor after main discharge; and
a reset circuit configured to reset the first magnetic switch and the second magnetic switch,
potential of the cathode electrode in a period of 0.5 μs to 20 μs both inclusive after the main discharge starts being within a range of −200 V to 200 V both inclusive.
